(19) United States
(12) Patent Application Publication
(10) Pub. No.: US 2026/0198303 A1
(43) Pub. Date: Jul. 9, 2026

(54) FLOATING METAL CAPACITOR

(71) Applicant: INTERNATIONAL BUSINESS MACHINES CORPORATION, Armonk, NY (US)

(72) Inventors: Kamal Rudra, Albany, NY (US); Lawrence Alfred Clevenger, Saratoga Springs, NY (US); Albert Manhee Chu, Nashua, NH (US); Koichi Motoyama, Clifton Park, NY (US)

(21) Appl. No.: 19/010,702

(22) Filed: Jan. 6, 2025

(51) Int. Cl. H01L 23/522; H01L 23/528; H10D 1/00; H10D 1/68

(52) U.S. Cl. CPC H10W 20/496; H10D 1/042; H10D 1/716; H10W 20/427; H10W 20/43; H10W 20/435

(57) ABSTRACT

A semiconductor device includes a plurality of metal lines and a capacitor dielectric conformally deposited on and between the plurality of metal lines. A plate is disposed within the capacitor dielectric between adjacent metal lines of the plurality of metal lines. The plate electrically floats within the capacitor dielectric to provide a floating capacitor between the adjacent metal lines.

### BACKGROUND

The present invention generally relates to semiconductor devices and processing methods, and more particularly to a capacitor structure that includes a floating plate between metal lines.

Layout area is at a premium for most semiconductor devices. To ease restrictions on layout area especially on a frontside of a device, backside devices structures devices are increasingly being employed. Among these structures, backside power distribution networks, which include a plurality of adjacent power supply lines have been used. In metal levels with metal lines in close proximity voltage spikes or noise in power rails can have a detrimental effect on signals or power within adjacent structures. Control of these voltage spikes or cross-coupled noise is needed.

### SUMMARY

In accordance with an embodiment of the present invention, a semiconductor device includes a plurality of metal lines and a capacitor dielectric conformally deposited on and between the plurality of metal lines. A plate is disposed within the capacitor dielectric between adjacent metal lines of the plurality of metal lines. The plate electrically floats within the capacitor dielectric to provide a floating capacitor between the adjacent metal lines.

In accordance with another embodiment of the present invention, a semiconductor device includes a plurality of metal lines including power rails having different supply voltages. A capacitor dielectric is conformally deposited on and between the plurality of metal lines. A plurality of plates is disposed between metal lines of the plurality of metal lines within the capacitor dielectric, wherein the plurality of plates electrically float within the capacitor dielectric to provide a floating capacitor between adjacent metal lines.

In accordance with another embodiment of the present invention, a method of forming a semiconductor device includes forming metal lines; conformally depositing a capacitor dielectric on and between the metal lines; and forming a plurality of plates within the capacitor dielectric between adjacent metal lines, wherein the plurality of plates electrically float within the capacitor dielectric to provide a floating capacitor between adjacent metal lines.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of patterned metal lines of a semiconductor device on lower layers, in accordance with an embodiment of the present invention;

FIG. 2 shows a cross-sectional view of the metal lines having a conformal capacitor dielectric formed over the metal lines, in accordance with an embodiment of the present invention;

FIG. 3 shows a cross-sectional view of a conductive material formed over the capacitor dielectric and in between the metal lines, in accordance with an embodiment of the present invention;

FIG. 4 shows a cross-sectional view of the conductive material recessed between the metal lines, in accordance with an embodiment of the present invention;

FIG. 5 shows a cross-sectional view of the capacitor dielectric etched to expose the metal lines, in accordance with an embodiment of the present invention;

FIG. 6 shows a top layout view depicting a region having a floating capacitor structure locally disposed on the metal lines and including air gaps regions, in accordance with an embodiment of the present invention;

FIG. 7 shows a cross-sectional view corresponding to the layout of FIG. 6, in accordance with an embodiment of the present invention;

FIG. 8 shows a cross-sectional view depicting an interlevel dielectric layer formed and the capacitor dielectric and metal lines having a top surface above a height of a plate, in accordance with an embodiment of the present invention;

FIG. 9 shows a cross-sectional view depicting an interlevel dielectric layer formed and the capacitor dielectric and metal lines having a top surface above a height of a plate and airgaps formed outside of a floating capacitor structure, in accordance with an embodiment of the present invention;

FIG. 10 shows a cross-sectional view depicting an interlevel dielectric layer formed and the metal lines having a top surface below a height of a plate and showing plates connected in groups by top conductors, in accordance with an embodiment of the present invention;

FIG. 11 shows a cross-sectional view depicting an interlevel dielectric layer formed and the metal lines having a top surface below a height of a plate and showing plates connected in groups by top conductors with airgaps formed outside of a floating capacitor structure, in accordance with an embodiment of the present invention;

FIG. 12 shows a cross-sectional view depicting an interlevel dielectric layer formed and the metal lines having a top surface below a height of a plate and showing plates connected by a top conductor, in accordance with an embodiment of the present invention;

FIG. 13 shows a cross-sectional view depicting an interlevel dielectric layer formed and the metal lines having a top surface below a height of a plate and showing plates connected by a top conductor with airgaps formed outside of a floating capacitor structure, in accordance with an embodiment of the present invention;

FIG. 14 shows a cross-sectional view depicting an interlevel dielectric layer formed and the metal lines having a top surface below a height of a plate, in accordance with an embodiment of the present invention;

FIG. 15 shows a cross-sectional view depicting an interlevel dielectric layer formed and the metal lines having a top surface below a height of a plate with airgaps formed outside of a floating capacitor structure, in accordance with an embodiment of the present invention;

FIG. 16 shows a cross-sectional view depicting floating plates directly contacting lower layers, in accordance with an embodiment of the present invention;

FIG. 17 shows a cross-sectional view depicting vias connecting to a top conductor and a metal line after formation of a cap dielectric, in accordance with an embodiment of the present invention;

FIG. 18 shows a cross-sectional view depicting an interconnect or via connecting to top portions of floating plates, in accordance with an embodiment of the present invention;

FIG. 19 shows a cross-sectional view depicting a top via formed, in accordance with an embodiment of the present invention;

FIG. 20 shows a cross-sectional view depicting a top via formed with airgaps formed outside of a floating capacitor structure, in accordance with an embodiment of the present invention;

FIG. 21 shows a top view and corresponding cross-sectional view of a semiconductor device with a floating capacitor structure spanning a portion of a length of metal lines, in accordance with an embodiment of the present invention; and

FIG. 22 is a diagram showing a plot of effective capacitance per area versus dielectric thickness for a number of different dielectric constant materials, in accordance with an embodiment of the present invention.

### DETAILED DESCRIPTION

In accordance with embodiments of the present invention, devices and methods are described which include capacitors disposed within and in between metal lines of a semiconductor device. In an embodiment, the capacitor includes a plate or plates that float. The floating plate is not connected to other conductive lines or structures. The floating plate or plates form a floating capacitor that is disposed within a dielectric material and is positioned between adjacent metal lines. Other plates may also be disposed within a dielectric material and positioned between adjacent metal lines. The plates of the floating capacitors can be connected to other plates of the floating capacitor. The floating capacitor includes a plurality of plates disposed within spaces between adjacent interconnects. In metal levels, the floating plates are selectively positioned to filter voltage spikes or to decouple noise between the interconnects. The interconnects can include power rails, signal lines or other conductive structures.

A floating capacitor has no need to connect to any line, although in some embodiments, the floating capacitor can connect to other conductive structures. The floating capacitor can be integrated as metal plates not connected to other hardware. The floating capacitor can have little impact on current semiconductor processing as the floating capacitor can easily be integrated within any metal interconnect structures using a same design and masking processes that would be employed without the floating capacitor.

Employing a floating capacitor in accordance with embodiments of the present invention can control capacitance by adjusting a thickness and area of the plates of the floating capacitor. In this way, a local capacitance/area can be enhanced by, e.g., 5 to 100 times that of conventional capacitors.

As used herein, the term “floating” may refer to a conductive structure or element that is electrically isolated from other conductive structures or elements in the device. A floating structure may not have a direct electrical connection to other components, power supplies, or ground, and may maintain an electric potential that is not fixed relative to other parts of the circuit. In some aspects, a floating structure may be capacitively coupled to nearby conductive elements without direct ohmic contact.

Embodiments of the present invention can include air gaps between adjacent interconnects that do not have the floating plates therebetween. The floating plates that form the floating capacitor can include dielectric that surrounds only selected power lines. The metal of the floating plates electrically floats and is surrounded by, e.g., a high-k dielectric. In other embodiments, multiple floating plates can be connected together. This can include an equal or unequal number of metal plates that can be connected together across a region. The floating plates can exist between one or more metal lines.

A height of dielectric can be equal to a metal line height be less than the metal line height or can be greater than the metal line height. In an embodiment, the floating plate can be recessed, and the floating plate can have a height that is less than the height of the metal line. The thickness (width) of the metal lines can be different than that of the floating plates of the floating capacitor. Different floating capacitor structures can exist on a same wafer or device.

A method of forming metal lines with a floating capacitor includes a metal deposition, patterning and trench etch. Via are patterned and a top via is etched. A high-k dielectric is deposited followed by the patterning and metal deposition for a capacitor. The metal is etched back followed by a dielectric deposition. The structure is patterned, and selective wet etching removal of the capacitor metal can be performed. A selective removal of high-k dielectric is performed. An interlevel dielectric layer (ILD) is deposited as a gap fill. A planarization process (e.g., chemical mechanical polishing (CMP) is performed, and a capping layer can be deposited.

In some embodiments, material for forming plates for the floating capacitor includes a metal that can be subtractively etched, e.g., W, Ru, etc. A high dielectric constant (high-k dielectric) material can be employed for an insulator that has good adhesion with the electrode material, e.g., Hafnium Oxide (HfOx), Strontium Titanate (STO) or other dielectric materials.

Embodiments of the present invention can be employed in any type of semiconductor device or chip. For example, the present embodiments can include functional circuits such as, e.g., mixed signal circuits, analog circuits, radio frequency (RF) circuits, memory devices, such as, e.g., dynamic random access memory (DRAM), embedded DRAM, logic operation circuits, input/output (IO) circuits, high performance computing (HPC) circuits, clock buffers, processors, or any other integrated circuit chip or combinations thereof.

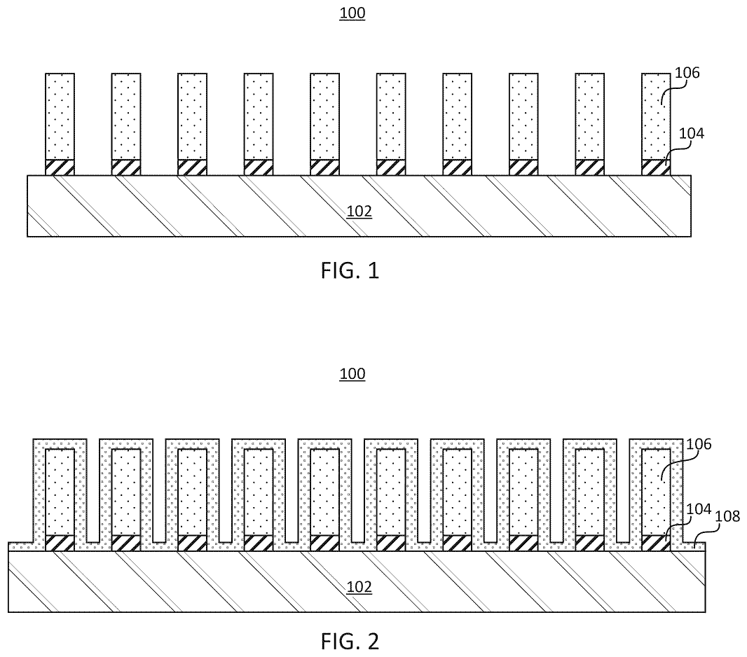

Referring now to the drawings in which like-numerals represent the same or similar elements and initially to FIG. 1, a cross-sectional view of a semiconductor device 100 is shown in accordance with an embodiment of the present invention. The semiconductor device 100 includes lower layers 102, which can include front end of line (FEOL) and middle of the line (MOL) devices and structures. In an embodiment, the lower layers 102 can include a dielectric layer that can be formed at any stage of the fabrication process. In an embodiment, the lower layers 102 can include an interlevel dielectric layer (ILD). The lower layers 102 can include one or more underlying layers, which can include a semiconductor substrate, active area components, metallization layers with dielectric material and any other structures needed for the operation of the semiconductor device 100.

The semiconductor substrate can include any suitable substrate structure, e.g., a bulk semiconductor, a semiconductor-on-insulator (SOI) substrate, etc., and preferably includes a monocrystalline semiconductor. In one example, the substrate can include a silicon-containing material. Illustrative examples of Si-containing materials suitable for the substrate can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc. The active area components can include, e.g., active regions, such as source/rain regions (S/D regions), gate structures, memory elements, diodes and any other electrical or electronic components. The active area components are electrically connected using vias/contacts and metal lines. The vias/contacts and metal lines are buried in dielectric material, which can include dielectric layers, such as, interlevel dielectric (ILD) layers.

In some embodiments, a barrier layer 104 or a stiction layer can be deposited. The barrier layer 104 is optional and can include TaN, TiN, or other materials that can assist with later deposited metals, e.g., Ru, employed for metal lines. A conductive deposition is performed to form metal lines 106. In an embodiment, the conductive deposition includes a blanket deposition to form a plate. The plate can subtractively etched or otherwise be patterned to form metal lines 106 and to etch through the barrier layer 104 to expose the lower layers 102. The plate can be deposited by chemical vapor deposition (CVD), atomic layer deposition (ALD), a physical vapor deposition (PVD) or any other suitable deposition method. The conductive deposition can include materials, such as, e.g., Ru, Mo, Rh, W, Ir, Cu and alloys or combinations of these and other conductive materials. In a particularly useful embodiment, the conductive deposition includes Ru.

The metal lines 106 are patterned using a hard mask and a lithographic patterning process. A hard mask (not shown) may be formed by blanket depositing a layer of hard mask material, providing a patterned photoresist on top of the layer of hard mask material. The patterned photoresist can be produced by applying a blanket photoresist layer to the surface of the hard mask material and exposing the photoresist layer to a pattern of radiation, and then developing the pattern into the photoresist layer utilizing resist developer.

The patterning process can include an extreme ultraviolet (EUV) double patterning process that includes patterning a mandrel using the photoresist material on the hard mask. A spacer is deposited over the photoresist mandrels and an electron beam etch is performed to remove the spacer from horizontal surfaces. A non-mandrel fill deposition is performed to fill in spaces between the spacers lines mandrels. A spacer pull is performed leaving an intermittent pattern of mandrels and non-mandrels (double pattern) along a surface of the hard mask. A trench etch is performed using the pattern of mandrels and non-mandrels to pattern the metal lines 106.

It should be noted that if the metal lines 106 include power rails (e.g., positive supply voltage (VDD) and/or negative supply voltage (VSS) then a minimum pitch may not be needed. If the minimum pitch is not needed additional space can be available between the metal lines 106 to provide greater leeway in customizing a size for floating plates for floating capacitor(s).

In an embodiment, the plate can be thick enough to form vias and metal lines 106. The via formed can be referred to as a top via (not shown). The top via can be formed by lithographically providing a block mask over the long metal lines and then etching the other metal lines to a desired height. The blocked portions form top vias and the other lines becomes the metal lines 106. Then, the top via block is removed.

Referring to FIG. 2, a capacitor dielectric 108 is deposited as a layer on the lower layers 102 and over the metal lines 106. The capacitor dielectric 108 can be deposited conformally or can be applied to have a different thickness on the sidewalls versus a top (e.g., over the metal lines 106, see e.g., FIG. 10). Etching or planarization can be employed to provide different thicknesses of the capacitor dielectric 108 on the sidewalls of the metal lines 106 versus the top of the metal lines 106 (top can be thicker or thinner than the sidewalls). This can be employed to modify floating capacitance as will be described.

The capacitor dielectric 108 can be deposited using a deposition method, such as, e.g., CVD, plasma enhanced CVD (PECVD), ALD or any other suitable deposition method. The capacitor dielectric 108 can include any dielectric material, but preferably includes a high-k dielectric material, such as, e.g., hafnium silicate, zirconium silicate, hafnium oxide (e.g., hafnium dioxide), zirconium oxide, silicon nitride, silicon oxide, lanthanum oxide, STO, etc. The capacitor dielectric 108 can include a thickness from about 1 nm to about 10 nm.

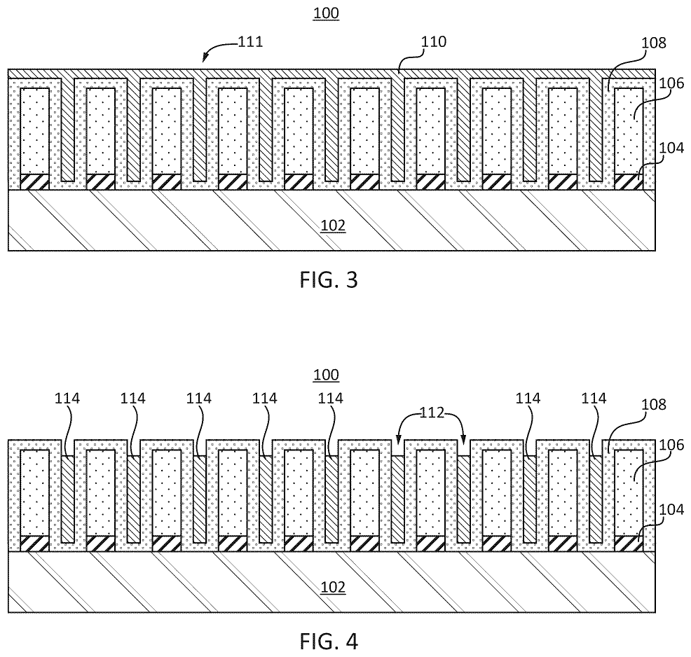

Referring to FIG. 3, a conductive material 110 is deposited to fill spaces between the capacitor dielectric 108 in between metal lines 106. A metal deposition and fill process to provide the conductive material 110 can include a deposition process, such as ALD, although CVD, PECVD, sputtering or other suitable deposition processes can be employed. The conductive material 110 can include a metal, such as, e.g., Cu, Co, Ru, W, etc. a metal compound, e.g., TaN, TiN, etc., or combinations of these or other conductive materials. The conductive material 110 can include a high or low resistivity metal (or a combination thereof) as the metal of the conductive material 110 will be employed predominantly for its capacitive properties as opposed to resistive properties. The conductive material 110 also covers a top portion 111 of the semiconductor device 100. The top portion 111 can be patterned to provide connections between plates 114 in some embodiments.

Referring to FIG. 4, a selective etch process is employed to remove the conductive material 110 in the top portion 111 and form a recess 112 over each plate 114 formed. The etch process can include a selective dry etch, although a wet etch or other selective etch can be employed.

In an embodiment, the plates 114, which are electrically floating, include a top surface below a top surface of the metal lines 106. A depth of the recess 112 can be employed as a performance parameter employed in adjusting a capacitance of floating capacitors to be formed. In some embodiments, the top portion 111 can be patterned to provide a connector between two or more plates 114.

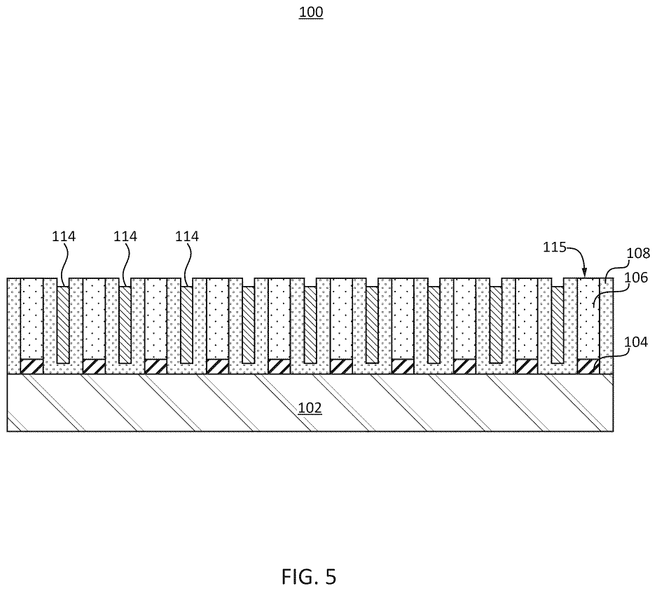

Referring to FIG. 5, a selective etch process is employed to remove the capacitor dielectric 108 from a surface of the metal lines 106 to expose a top surface 115 of the metal lines 106. The etch process can include a selective dry etch, although a wet etch or other selective etch can be employed.

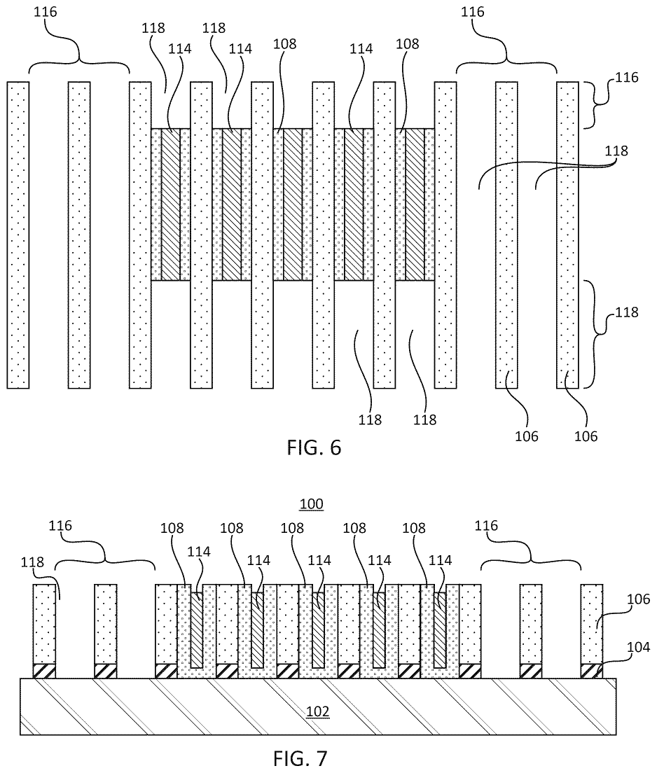

Referring to FIG. 6, a top view of the semiconductor device 100 is shown in accordance with an embodiment. In the embodiment shown, a selective etch is performed to remove the capacitor dielectric 108 from regions 116 where floating capacitors are not needed or wanted. An etch mask (not shown) is formed over the semiconductor device 100 and patterned to preserve the capacitor dielectric 108 and the plates 114 in a region where a floating capacitor is desired. The selective etch removes the capacitor dielectric 108 and the conductive material 110 of the plates 114 from the regions 116. The regions 116 can be employed to form airgaps 118 or can be filled with a different dielectric material or materials.

Referring to FIG. 7, a cross-sectional view is shown of the semiconductor device 100 of FIG. 6. The etch mask is removed leaving the airgaps 118 formed in the regions 116.

Referring to FIGS. 8-15, different configurations are shown for floating capacitors in accordance with embodiments of the present invention.

FIG. 8 shows the semiconductor device 100 after an interlayer dielectric layer 120 (ILD) is deposited as a gap fill and planarized. The ILD 120 can include any suitable material, e.g., SiO₂, Si₃N₄, SiOₓN_{y}, SiC, SiCO, SiCOH, and SiCH compounds, the above-mentioned materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The ILD 120 can be deposited using CVD, although other deposition methods can be employed. The ILD 120 can be planarized using, e.g., a chemical mechanical polish (CMP).

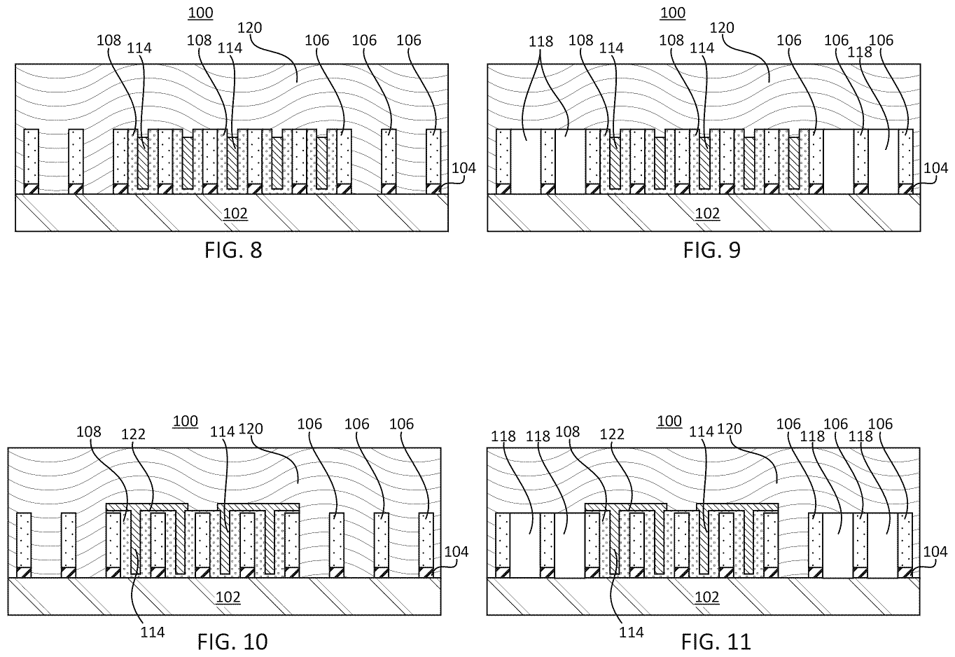

FIG. 9 shows the semiconductor device 100 of FIG. 8 having airgaps 118 selectively formed after the ILD 120 is deposited and planarized. The airgaps 118 can be formed by depositing a sacrificial material in the airgaps 118, during the fabrication process, between the metal lines 106 where the airgaps 118 are to be formed. Then, the sacrificial material is selectively etched away, leaving behind an empty space or airgaps 118 between the metal lines 106. Other methods for forming airgaps 118 can also be employed.

FIG. 10 shows the semiconductor device 100 with a top conductor 122 formed during the deposition of the conductive material 110 (FIG. 3) and patterned using an etch mask to remain after etching to form a connection between the plates 114. The conductor 122 can be formed to connect groups of two or more plates 114 and can be configured in accordance with the etch pattern to connect any number of plates 114. The ILD 120 is deposited and planarized.

FIG. 11 shows the semiconductor device 100 of FIG. 10 having airgaps 118 selectively formed after the ILD 120 is deposited and planarized.

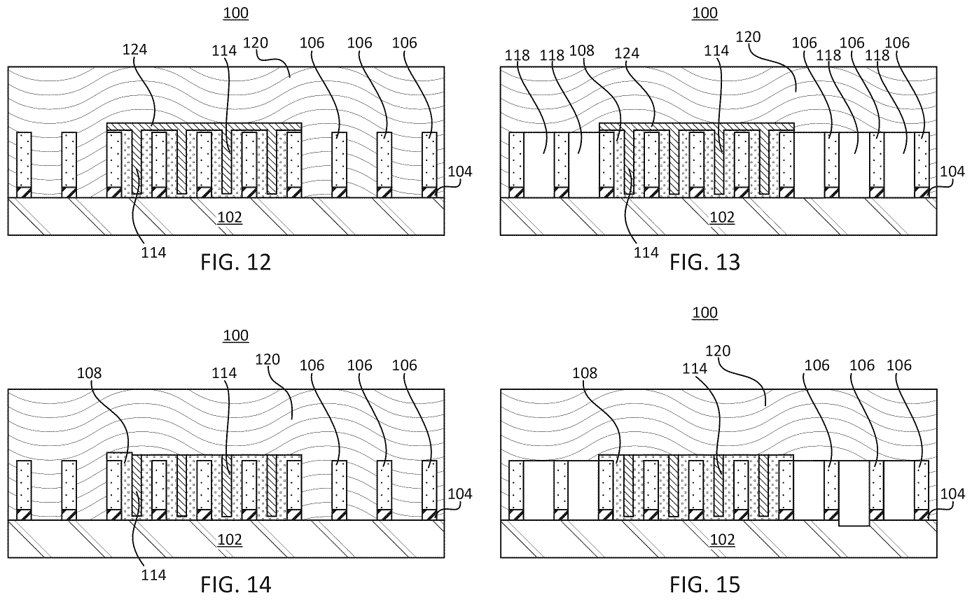

FIG. 12 shows the semiconductor device 100 with a top conductor 124 formed during the deposition of the conductive material 110 (FIG. 3) and patterned using an etch mask to remain after etching to form a connection between the plates 114. The conductor 124 can be formed to connect all of the plates 114 in a particular region and can be configured in accordance with the etch pattern to connect the plates 114 in a selected group. The ILD 120 is deposited and planarized.

FIG. 13 shows the semiconductor device 100 of FIG. 12 having airgaps 118 selectively formed after the ILD 120 is deposited and planarized.

FIG. 14 shows the semiconductor device 100 with the plates 114 extended above a height of the metal lines 106. The height of the plates 114 can be controlled. For example, instead of recessing the conductive material 110 in FIG. 4, the conductive material 110 can be planarized, e.g., by CMP, to a level of the capacitor dielectric 108. The ILD 120 is then deposited and planarized.

FIG. 15 shows the semiconductor device 100 of FIG. 14 having airgaps 118 selectively formed after the ILD 120 is deposited and planarized.

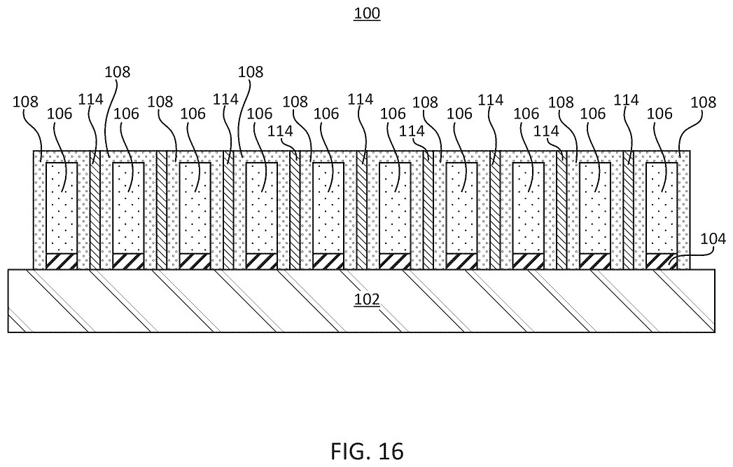

Referring to FIG. 16, in other embodiments, the capacitor dielectric 108 can be removed from horizontal surfaces (e.g., by an etch process) in between metal lines 106. This permits the plates 114 to extend further and directly contact the lower layers 102. The embodiments where the plates 114 contact the lower layers 102 directly can be employed in any and all of the embodiments described herein.

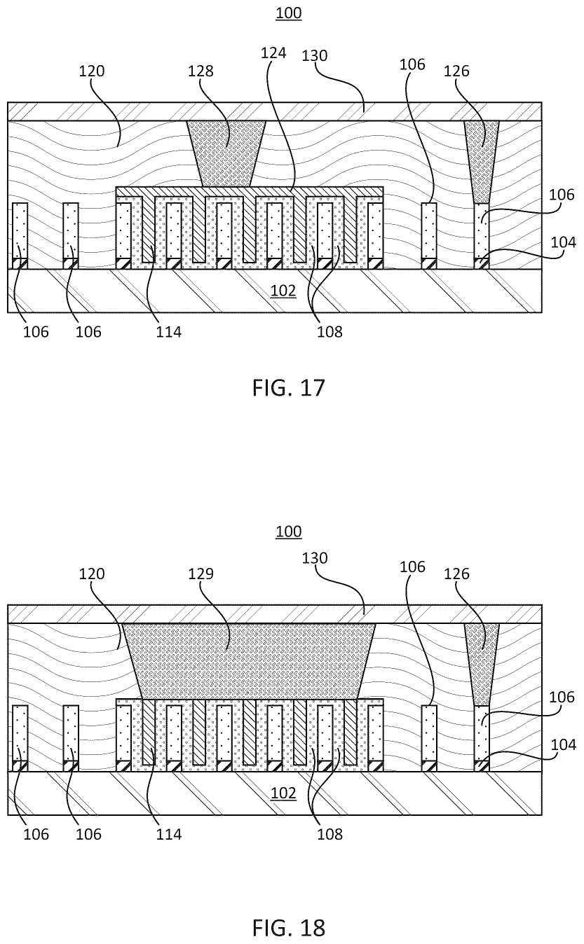

Referring to FIG. 17, processing can continue with the formation of additional metal structures for any or all of the embodiments. In an embodiment, the conductor 124 can be connected to other structures using a via 128 or contact. The contact or via 128 can provide a common connection and maintain the electrically floating status of the plates 114. The via 128 can connect to other structures. Additional vias 126 can be included to connect to metal lines 106. Openings or holes can be patterned into the ILD 120. The openings can include a diffusion barrier that can be formed in the openings prior to a conductive fill. The diffusion barrier can include, e.g., TiN, TaN, or similar materials.

A conductive fill can be performed to fill the openings on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form via 126 and via 128. A dielectric cap 130 can be deposited and opened up as needed to make connection to the via 126, via 128 and/or the metal lines 106. The dielectric cap 130 can include a thickness of between about 2 nm and about 8 nm.

Referring to FIG. 18, in an embodiment, the conductor 124 can be omitted and an interconnect 129 or via can provide a common connection between plates 114. The interconnect 129 can maintain the electrically floating status of the plates 114. The interconnect 129 can also connect to other structures as well as serve as a connection between the plates 114.

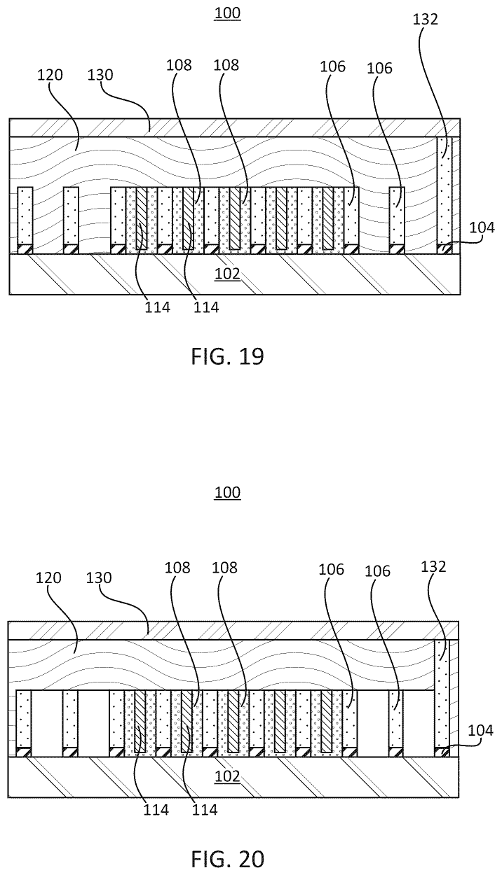

Referring to FIG. 19, a top via 132 can be formed. The top via 132 can be formed with the other metal lines 106. The metal lines 106 are formed having a large height. The large height is reduced for the metal lines 106 and maintained for the top via 132 by employing a block mask (not shown). During the planarization process of the ILD 120 (FIGS. 8-15), the top via 132 is revealed so that it can be connected to other metal structures to be formed.

Referring to FIG. 20, the semiconductor device 100 of FIG. 19 is shown with the top via 132 and airgaps 118 selectively formed after the ILD 120 is deposited and planarized.

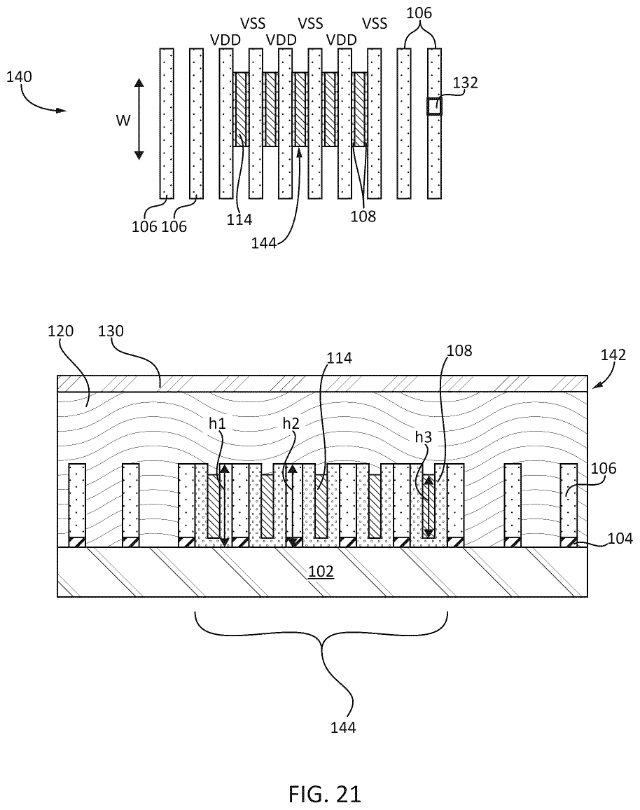

Referring to FIG. 21, a layout or top view 140 and a cross-section view 142 are shown for an interconnect structure in accordance with embodiments of the present invention. The top view 140 shows the metal lines 106 being employed as power rails. The power rails can alternate between VDD and VSS. A region 144 includes floating capacitors. The floating capacitors include the plates 114 which include an electrically floating metal in a high dielectric constant material of the capacitor dielectric 108. Although the region 144 is shown occupying only a partial length (W) portion of the metal lines 106, the regions can extend an up to an entire length of the metal lines or any portion thereof.

The capacitor dielectric 108 surrounds only selected metal lines 106. The floating metal of the plates 114 is surrounded by the high-k dielectric of the capacitor dielectric 108. Multiple plates 114 can be connected together in equal or unequal groups of plates 114. The floating metal capacitance structure can be disposed between one or more metal lines 106. A height h1 of the capacitor dielectric 108 can be equal to a height h2 of the metal lines 106. In other embodiments, h1<h2 (e.g., if a recess is employed) or h1>h2 (if no dielectric etch back has been employed). A height h3 for the plate 114 that is recessed can have h3<h1. In other embodiments, h3=h1 or h3>h1.

It should be understood that different floating capacitors structures can be employed in different regions (or a same region) of a same semiconductor device 100. Different combinations of floating capacitor embodiments on the same wafer or semiconductor device 100 are contemplated to locally or globally place floating capacitors to filter voltage spikes or noise in power rails or other metal lines.

The plates 114 of the floating capacitor structure do not need to connect to any line or connection and provide passive capacitance between the metal lines 106, which can include power rails. Since the plate 114 is floating and does not need to be connected to other conductors or hardware, the plates 114 can be placed anywhere in a design layout and on one or more levels, as needed. The capacitance can be easily controlled by a thickness as well as an area of each plate 114, and a thickness and material selection for the capacitor dielectric 108. Local capacitance capacitance/area can be enhanced by, e.g., between about 10 and 100 times over designs with adjacent metal lines alone.

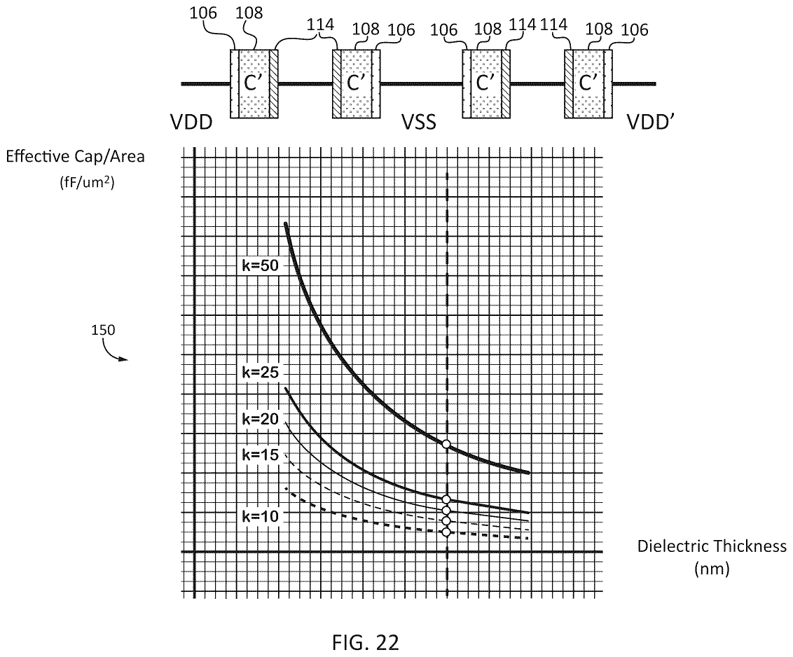

Referring to FIG. 22, a diagram 150 shows effective capacitance per area plotted against dielectric thickness for a plurality of dielectric constants (k). The effective capacitance per area has units of fF/μm². The dielectric thickness has units of nm. The dielectric constant is plotted for k=10, 15, 20, 25 and 50. The plots were generated with three metal lines 106 (power rails including VDD, VSS and VDD′). VDD and VDD′ include a same voltage and dimensions. Plates 114 were disposed between the power rails and floated in capacitor dielectric 108 to form a floating capacitor structure in accordance with the present embodiments. An effective capacitance between the power rails adds in series (from metal lines to plate and plate to metal lines) and then in parallel (across the three metal lines) to provide an effective capacitance between VDD and VSS of: (C′/2)+(C′/2)=C′. Comparing this to a device without the floating metal structure yields only a parallel combination of capacitance or 2C across the three metal lines. Then, the effective capacitance for a combination of three lines VDD, VSS and VDD′ for the present embodiments is 2C′ as compared to 2C without floating metal plates and here C′>>C. In this way, a local capacitance/area can be enhanced by, e.g., about 5 to about 100 times over that of conventional capacitors. Other improvements in capacitance/area are also contemplated.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor-or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a plurality of metal lines;
a capacitor dielectric conformally deposited on and between the plurality of metal lines; and
a plate disposed within the capacitor dielectric between adjacent metal lines of the plurality of metal lines, wherein the plate electrically floats within the capacitor dielectric to provide a floating capacitor between the adjacent metal lines.

2. The semiconductor device of claim 1, wherein the plate includes a top surface that is recessed below a top surface of the plurality of metal lines.

3. The semiconductor device of claim 1, further comprising a conductor formed over the plate that connects the plate to at least one other plate that floats within the capacitor dielectric.

4. The semiconductor device of claim 1, wherein the plate includes a top surface that extends above a top surface of the plurality of metal lines.

5. The semiconductor device of claim 1, wherein the plurality of metal lines includes airgaps in spacings therebetween.

6. The semiconductor device of claim 1, wherein the plate extends a portion of a length of the plurality of metal lines.

7. The semiconductor device of claim 1, wherein at least two plates are electrically connected to each other over a top portion of the plurality of metal lines.

8. The semiconductor device of claim 1, wherein the plate is configured to filter voltage spikes and noise between the adjacent metal lines.

9. A semiconductor device, comprising:
a plurality of metal lines including power rails including different supply voltages;
a capacitor dielectric conformally deposited on and between the plurality of metal lines; and
a plurality of plates disposed between metal lines of the plurality of metal lines within the capacitor dielectric, wherein the plurality of plates electrically float within the capacitor dielectric to provide a floating capacitor between adjacent metal lines.

10. The semiconductor device of claim 9, wherein the plurality of plates includes top surfaces that are recessed below a top surface of the plurality of metal lines.

11. The semiconductor device of claim 9, further comprising a conductor formed over the plurality of plates that connects the plurality of plates.

12. The semiconductor device of claim 9, wherein the plurality of plates include top surfaces that extends above a top surface of the plurality of metal lines.

13. The semiconductor device of claim 9, wherein the plurality of metal lines include airgaps in spacings between metal lines where the plurality of plates are not present.

14. The semiconductor device of claim 9, wherein the plurality of plates extend a portion of a length of the plurality of metal lines.

15. The semiconductor device of claim 9, wherein at least two plates are electrically connected to each other over a top portion of the plurality of metal lines.

16. The semiconductor device of claim 9, wherein a capacitance between adjacent metal lines having a plate therebetween is between about 5 and 100 times greater than a capacitance between adjacent metal lines without the plate therebetween.

17. The semiconductor device of claim 9, wherein the plurality of plates is configured to filter voltage spikes and noise between the adjacent metal lines.

18. A method of forming a semiconductor device, comprising:
forming metal lines;
conformally depositing a capacitor dielectric on and between the metal lines; and
forming a plurality of plates within the capacitor dielectric between adjacent metal lines, wherein the plurality of plates electrically float within the capacitor dielectric to provide a floating capacitor between adjacent metal lines.

19. The method of claim 18, further comprising recessing top surfaces of the plurality of plates below top surfaces of the metal lines.

20. The method of claim 18, further comprising forming a conductor electrically connects at least two of the plurality of plates to each other.
